(19) United States
(12) Patent Application Publication
(10) Pub. No.: US 2007/0224785 A1
(43) Pub. Date: Sep. 27, 2007

(54) Strain-inducing film formation by liquid-phase epitaxial re-growth

(76) Inventor: Mark Y. Liu, Portland, OR (US)

Correspondence Address: INTEL/BLAKELY, 1279 OAKMEAD PARKWAY, SUNNYVALE, CA, 94085-4040, US

(21) Appl. No.: 11/386,518

(22) Filed: Mar. 21, 2006

(51) Int. Cl. H01L 21/20; H01L 21/36

(52) U.S. Cl. 438/478

(57) ABSTRACT

A method to form a strain-inducing three-component epitaxial film is described. In an embodiment, a three-component epitaxial film comprises atoms from a parent film, charge-neutral lattice-substitution impurities and charge carrier dopant impurities. In one embodiment, the charge-neutral lattice-substitution impurities are smaller and present in greater concentration than the charge carrier dopant impurities.

### BACKGROUND OF THE INVENTION

1) Field of the Invention

The invention is in the field of Semiconductor Devices.

2) Description of Related Art

For the past several years, the performance of semiconductor devices, such as Metal Oxide Semiconducter Field-Effect Transistors (MOS-FETs), has been greatly enhanced by the incorporation of strained silicon regions into the active portions of a semiconductor substrate, e.g. the use of compressively strained silicon channel regions to enhance hole mobility in P-type Metal Oxide Semiconductor Field-Effect Transistors (PMOS-FETs). The presence of such strained silicon regions may greatly enhance the rate at which charge migrates in a channel when a semiconductor is in an ON state.

FIG. 1 depicts a typical strained PMOS-FET 100 fabricated on a substrate 102. A gate dielectric layer 104 sits above a channel region 106 and a gate electrode 108 sits above a gate dielectric layer 104. Gate dielectric layer 104 and gate electrode 108 are isolated by gate isolation spacers 110. Tip extensions 112 are formed by implanting dopant atoms into substrate 102. Strain-inducing source/drain regions 120 are formed by selectively growing an epitaxial film in etched-out portions of substrate 102 and are doped either in situ or after epitaxial film growth, or both. Strain-inducing source/drain regions are comprised of a material with a larger lattice constant than that of the channel region 106. In typical PMOS-FETs, the channel region 106 is comprised of crystalline silicon, while the strain-inducing source/drain regions 120 are comprised of epitaxial silicon/germanium which has a larger lattice constant than that of crystalline silicon. Strain-inducing source/drain regions 120 can invoke a uniaxial compressive strain on the channel region 106. Such a compressive strain in the channel region 106 can enhance the hole mobility in the channel region 106 of PMOS-FET 100, lending to improved performance of the device.

FIGS. 2A-C illustrate a typical process flow for forming strain-inducing source/drain regions in a PMOS-FET. Referring to FIG. 2A, a non-strained PMOS-FET 200 is first formed. Non-strained PMOS-FET 200 is comprised of a channel region 206. A gate dielectric layer 204 sits above the channel region 206 and a gate electrode 208 sits above gate dielectric layer 204. Gate dielectric layer 204 and gate electrode 208 are isolated by gate isolation spacer 210. Tip extensions 212 and source/drain regions 214 are formed by implanting dopant atoms into substrate 202. Thus, Therefore, the lattice mismatch between the source/drain regions 214 and the channel region 206 is negligible, resulting in effectively no strain on the channel region 206. Referring to FIG. 2B, portions of substrate 202, including source/drain regions 214, are removed, e.g. by an etch process, to form recessed regions 216 in substrate 202. Subsequently, strain-inducing source/drain regions 220 are formed by selectively growing an epitaxial film into recessed regions 216, as depicted in FIG. 2C. Strain-inducing source/drain regions 220 can be doped with charge carrier atoms, e.g. boron in the case of a PMOS-FET, which may be done in situ (during the deposition of the epitaxial film) or after epitaxial film growth (which may require a subsequent anneal process), or both. In an example, substrate 202, and hence channel region 206, is comprised of crystalline silicon and the film grown to form strain-inducing source/drain regions 220 is comprised of epitaxial silicon/germanium. The lattice constant of the epitaxial silicon/germanium film can be greater than that of crystalline silicon by a factor of ˜1% (for 70% Si, 30% Ge) and so strain-inducing source/drain regions 220 are comprised of a material with a larger lattice constant than that of the channel region 206. Therefore, a uniaxial compressive strain, depicted by the arrows in FIG. 2C, is rendered on channel region 206 in PMOS-FET 230, which can enhance hole mobility in the device.

In order to improve performance in N-type Metal Oxide Semiconductor Field-Effect Transistors (NMOS-FETs), a uniaxial tensile strain may be required to enhance electron mobility in the channel region. This may require incorporation of strain-inducing source/drain regions with a smaller lattice constant than that of the channel region. For example, epitaxial carbon-doped silicon source/drain regions may be desirable for NMOS-FETs with a crystalline silicon channel region because the lattice constant of epitaxial carbon-doped silicon is smaller than that of crystalline silicon. However, selective deposition of an epitaxial carbon-doped silicon film can be difficult. Furthermore, subsequent incorporation of N-type dopants, e.g. phosphorus, into such an epitaxial carbon-doped silicon film may irreversibly modify the film by displacing the lattice-incorporated carbon atoms. Such displacement of lattice-incorporated carbon atoms may reduce the lattice constant differential between the resulting source/drain regions and the channel region, effectively mitigating any performance-enhancing strain induced on the channel region. Thus, a method to fabricate an N-type epitaxial carbon-doped silicon film is described herein.

### BRIEF DESCRIPTION OF THE DRAWINGS

FIG. 1 illustrates a cross-sectional view of a strained P-type Metal Oxide Semiconductor Field-Effect Transistor (PMOS-FET), in accordance with the prior art.

FIGS. 2A-C illustrate cross-sectional views representing the formation of a PMOS-FET with strain-inducing source/drain regions, in accordance with the prior art.

FIGS. 3A-E illustrate cross-sectional views representing the formation by liquid-phase epitaxial re-growth of a three-component epitaxial film in a crystalline substrate, in accordance with an embodiment of the present invention.

FIGS. 4A-E illustrate cross-sectional views representing the formation by liquid-phase epitaxial re-growth of a three-component epitaxial film in an etched-out region of a crystalline substrate, in accordance with an embodiment of the present invention.

FIGS. 5A-F illustrate cross-sectional views representing the formation strain-inducing source/drain regions in an NMOS-FET, in accordance with an embodiment of the present invention.

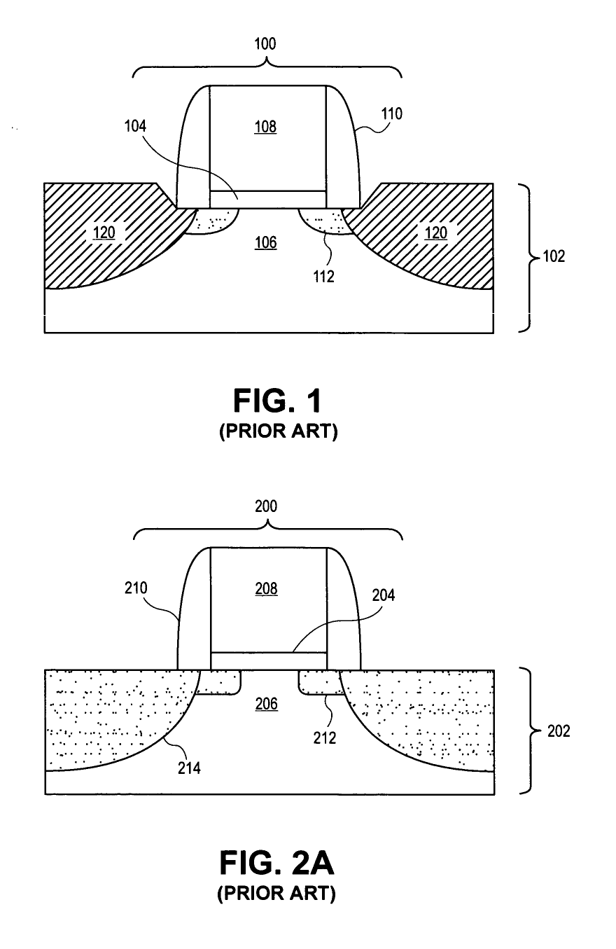

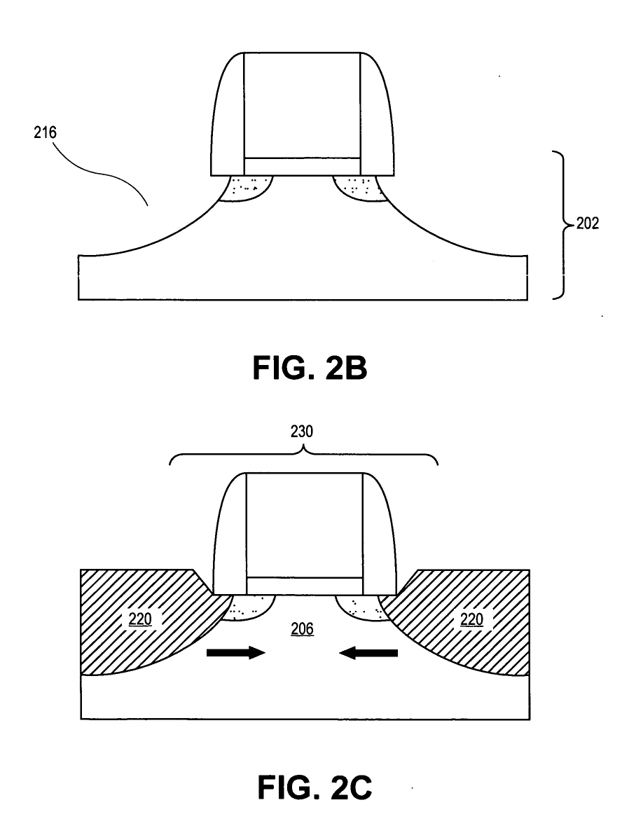

### DETAILED DESCRIPTION

A process for fabricating semiconductor devices and the resultant devices are described. In the following description, numerous specific details are set forth, such as specific dimensions and chemical regimes, in order to provide a thorough understanding of the present invention. It will be apparent to one skilled in the art that the present invention may be practiced without these specific details. In other instances, well-known processing steps, such as patterning steps or wet chemical cleans, are not described in detail in order to not unnecessarily obscure the present invention. Furthermore, it is understood that the various embodiments shown in the figures are illustrative representations and are not necessarily drawn to scale.

Disclosed herein is a method to form a three-component, strain-inducing epitaxial film. Formation of the strain-inducing epitaxial film by liquid-phase epitaxial re-growth may enable a much higher strain and doping activation than that achieved by other methods. For example, an epitaxial carbon-doped silicon film fabricated in this way may incorporate a substantial amount of phosphorus as an N-type dopant while maintaining a significant amount of carbon atoms substituted in the silicon lattice. The lattice constant of the epitaxial N-type carbon-doped silicon film may be smaller than the lattice constant of the crystalline silicon in the channel region, resulting in a tensile strain induced in the channel region. An NMOS-FET with source/drain regions comprised of such an epitaxial N-type carbon-doped silicon film and a channel region comprised of crystalline silicon may have an enhanced electron mobility in the channel region when in an ON state.

Liquid-phase epitaxial re-growth is a method in which a material is heated to or beyond its melting point, caused to melt, and subsequently cooled in a manner that the new solid phase formed, i.e. the re-growth phase, is a crystalline phase such as a single-crystal phase. Liquid-phase epitaxial re-growth is particularly useful for circumstances in which a material has an amorphous state with a melting point substantially lower than the melting point of its corresponding crystalline state. For example, the melting point of amorphous silicon is approximately 250° C. lower than that of crystalline silicon, enabling a large process window. Amorphous silicon regions formed within a crystalline silicon substrate may thus be controllably melted without melting the substrate itself. Upon cooling the melted, initially amorphous, silicon regions within the crystalline substrate, epitaxial silicon regions may form. Thus, a method of liquid-phase epitaxial re-growth may be used to form epitaxial silicon regions within a crystalline silicon substrate.

Charge carrier dopant impurities, e.g. phosphorus or boron, or charge-neutral lattice-substitution impurities, e.g. carbon or germanium, may be used to form an impurity-containing amorphous silicon region by damaging a portion of the silicon within a crystalline silicon substrate or may be incorporated into an already amorphized region to form an impurity-containing amorphous crystalline silicon substrate, a melted impurity-containing silicon region may form. The diffusion coefficients of impurities in liquid-phase silicon can be several orders of magnitude higher than in solid-phase silicon. Thus, by selecting an appropriate duration of melt time, the impurities may fully and uniformly diffuse in the liquid-phase silicon region to form an abrupt impurity edge at the interface of the liquid-phase silicon and the crystalline silicon substrate.

Upon cooling, the liquid phase silicon region with uniform dopant and lattice-substitution impurities may form an epitaxial film which incorporates these impurities into its lattice. Thus, a three-component epitaxial system may be formed, wherein the system is comprised of atoms from the parent film, charge carrier dopant impurity atoms and charge neutral lattice-substitution impurity atoms. For example, in accordance with an embodiment of the present invention, an epitaxial silicon region is formed which comprises carbon charge neutral lattice-substitution impurities to modify the size of the lattice and phosphorus charge carrier dopant impurities to satisfy the charge carrier requirements of that particular region. Additionally, impurities may have a considerably higher solubility constant in liquid-phase silicon than in solid-phase silicon. This increased solubility may enable a greater incorporation of such impurities into the resulting epitaxial silicon regions by the above described liquid-phase epitaxy method, resulting in greater strain and dopant activation in the epitaxial films fabricated by this method.

A three-component epitaxial film containing charge neutral lattice-substitution impurities and charge carrier dopant impurities may be formed wherein the charge neutral lattice-substitution impurities are smaller and present in greater concentration than the charge carrier dopant impurities. In accordance with an embodiment of the present invention, an epitaxial silicon film containing carbon lattice-substitution impurities and phosphorus charge carrier dopant impurities is formed in a crystalline silicon substrate. In one embodiment, the concentration of lattice-substituting carbon atoms is in the range of 1%-3% of the total film atomic composition and the concentration of the phosphorus charge carrier dopant impurities is in the range of 2E19 atoms/cm³-2E21 atoms/cm³. In another embodiment, the lattice constant of the three-component epitaxial film is in the range of 0.2%-1.0% smaller than the lattice constant for crystalline silicon.

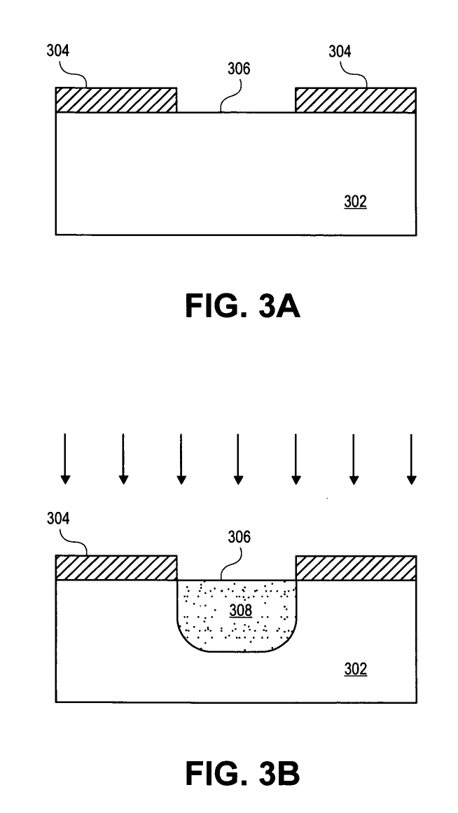

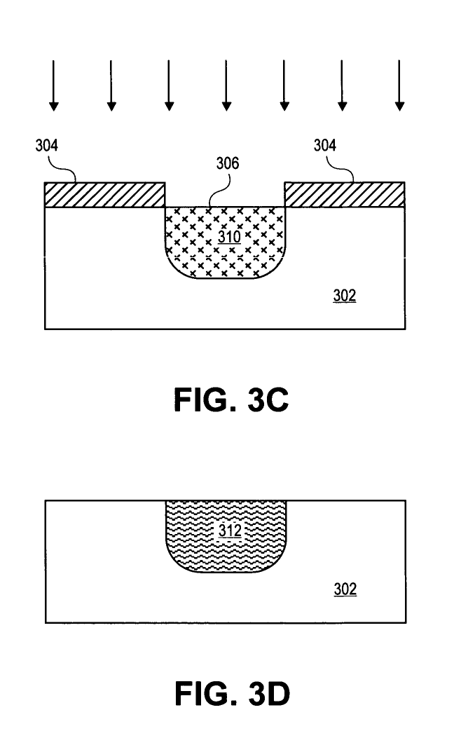

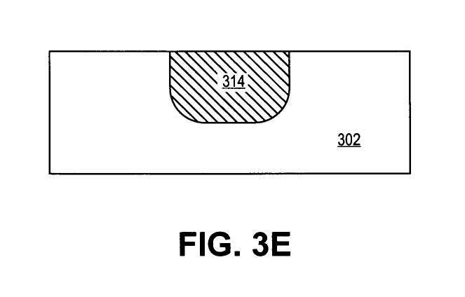

As an example of one embodiment of the present invention, FIGS. 3A-E illustrate the formation by liquid-phase epitaxial re-growth of a three-component strain-inducing epitaxial film in a crystalline substrate. Referring to FIG. 3A, a crystalline substrate 302 may be masked by masking layer 304 with an opening 306. In one embodiment of the present invention, crystalline substrate 302 is a crystalline silicon substrate. In another embodiment, crystalline substrate 302 is an epitaxial silicon layer grown atop a distinct crystalline silicon substrate. In one embodiment, crystalline substrate 302 is comprised of germanium or a III-V material such as but not limited to gallium nitride, gallium phosphide, gallium arsenide, indium phosphide or indium antimonide.

Referring to FIG. 3B, an amorphous region 308 may be formed in crystalline substrate 302. In an embodiment, amorphous region 308 is formed by implanting like atoms into crystalline substrate 302. In one embodiment, amorphous region 308 is formed in a crystalline silicon substrate by implanting silicon atoms through the opening 306 of masking layer 304 at a dose in the range of 1E14 atoms/cm²-2E15 atoms/cm² with an energy in the range of 2 keV-40 keV. In one embodiment, amorphous region 308 is formed at the time of implanting charge-neutral lattice-substitution impurities and charge carrier dopant impurities.

Referring to FIG. 3C, charge-neutral lattice-substitution impurities and charge carrier dopant impurities may be implanted through the opening 306 in masking layer 304 into crystalline substrate 302 or amorphous region 308, or both, to form three-component amorphous region 310 in crystalline substrate 302. In an embodiment, crystalline substrate 302 is comprised of silicon, the charge-neutral lattice-substitution impurities are carbon atoms and the charge carrier dopant impurities are phosphorus atoms. In one embodiment, the concentration of lattice-substituting carbon atoms is in the range of 1%-3% of the total film atomic composition and the concentration of the phosphorus dopant impurities is in the range of 2E19 atoms/cm³-2E21 atoms/cm³.

Masking layer 304 may then be removed and the structure formed in association with FIG. 3C may then be heated to a temperature sufficient to melt three-component amorphous region 310, but less than the temperature at which crystalline substrate 302 melts. Referring to FIG. 3D, three-component amorphous region 310 may be heated to form three-component melted region 312 within crystalline substrate 302. In one embodiment, three-component amorphous region 310 contains silicon, carbon and phosphorus atoms and is heated to a temperature of at least 1150° C. (to form three-component melted region 312), but not exceeding 1400° C. In another embodiment of the present invention, three-component amorphous region 310 is melted to form three-component melted region 312 by using a thermal annealing process or a laser irradiation process. Three-component melted region 312 may be generated for a duration sufficient to form a homogeneous system, in which the lattice-substitution impurities and the charge carrier dopant impurities have diffused evenly throughout three-component melted region 312. In one embodiment, three-component melted region 312 is generated for a duration of 10 nanoseconds-1000 nanoseconds.

Referring to FIG. 3E, the structure formed in association with FIG. 3D may be cooled below the melting temperature of three-component melted region 312 to re-solidify and form an epitaxial three-component re-growth region 314. In one embodiment, three-component re-growth region 314 has a lattice constant smaller than the lattice constant of crystalline substrate 302 and induces a tensile strain on crystalline substrate 302. In another embodiment, three-component re-growth region 314 has a lattice constant larger than the lattice constant of crystalline substrate 302 and induces a compressive strain on crystalline substrate 302. In one embodiment, three-component re-growth region is a homogeneous epitaxial silicon film comprised of carbon lattice-substitution impurities in a concentration range of 1%-3% of the total film atomic composition and phosphorus charge carrier dopant impurities with a concentration in the range of 2E19 atoms/cm³-2E21 atoms/cm³.

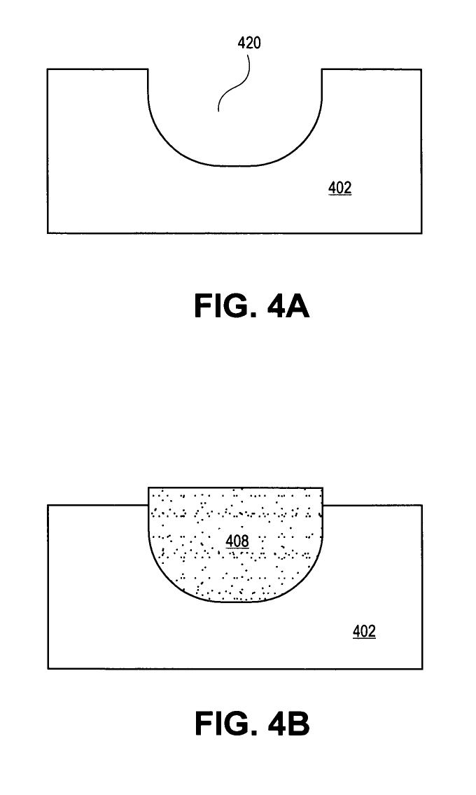

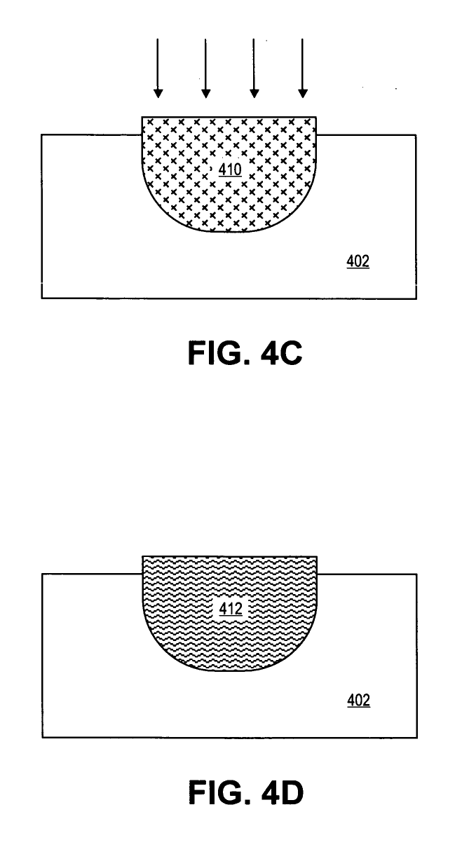

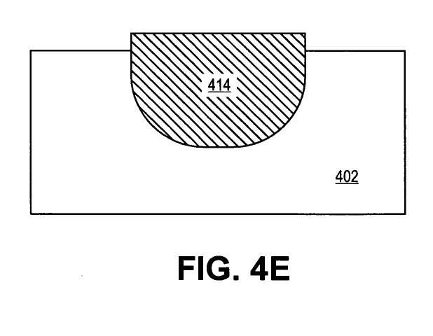

As an example of another embodiment of the present invention, FIGS. 4A-E illustrate the formation by liquid-phase epitaxial re-growth of a three-component epitaxial film in an etched out region of a crystalline substrate. Referring to FIG. 4A, a region of crystalline substrate 402 may be removed to form etched-out region 420. In one embodiment of the present invention, crystalline substrate 402 is a crystalline silicon substrate, a doped crystalline silicon substrate, or an epitaxial silicon layer grown atop a distinct crystalline silicon substrate. In another embodiment, crystalline substrate 402 is comprised of germanium or a III-V material such as but not limited to gallium nitride, gallium phosphide, gallium arsenide, indium phosphide or indium antimonide. In one embodiment of the present invention, etched out region 420 is formed by first masking crystalline substrate 402 with a masking layer and then etching any exposed portions of crystalline substrate 402 with a dry etch or wet etch process.

Referring to FIG. 4B, a material region 408 may be formed in etched-out region 420 of crystalline substrate 402. In one embodiment, material region 408 is an epitaxial silicon layer or an epitaxial carbon-doped silicon layer formed in a crystalline silicon substrate. In another embodiment, material region 408 is an amorphous silicon or carbon-doped silicon layer formed in a crystalline silicon substrate. In an embodiment, material region 408 is an amorphous or epitaxial silicon or carbon-doped silicon layer, doped with phosphorus atoms in situ, formed in a crystalline substrate. In one embodiment, material region 408 is an epitaxial silicon layer or an epitaxial carbon-doped silicon layer that is subsequently made amorphous by implanting silicon atoms into material region 408. In another embodiment, material region 408 is made amorphous at the time of implanting charge-neutral lattice-substitution impurities or charge carrier dopant impurities. In one embodiment, the top surface of material region 408 is raised above the top surface of crystalline substrate 402, as depicted in FIG. 4B.

Referring to FIG. 4C, charge-neutral lattice-impurities and charge carrier dopant impurities may be implanted into material region 408 to form three-component amorphous region 410 in crystalline substrate 402. In one embodiment, starting material region 408 is comprised of silicon, the charge-neutral lattice-substitution impurities are carbon atoms and the charge carrier dopant impurities are phosphorus atoms. In another embodiment, material region 408 is comprised of carbon-doped silicon and phosphorus dopant atoms are added to form three-component amorphous region 410. In one embodiment, the concentration of lattice-substituting carbon atoms is in the range of 1%-3% of the total film atomic composition and the concentration of the phosphorus charge carrier dopant impurities is in the range of 2E19 atoms/cm³-2E21 atoms/cm³.

The structure formed in association with FIG. 4C may then be heated to a temperature sufficient to melt three-component amorphous region 410, but less than the temperature at which crystalline substrate 402 melts. Referring to FIG. 4D, three-component amorphous region 410 may be heated to form three-component melted region 412 within crystalline substrate 402. In one embodiment, three-component amorphous region 410 contains silicon, carbon and phosphorus atoms and is heated to a temperature of at least 1150° C. (to form three-component melted region 412), but not exceeding 1400° C. In another embodiment of the present invention, three-component amorphous region 410 is melted to form three-component melted region 412 by using a thermal annealing process or a laser irradiation process. Three-component melted region 412 may be generated for a duration sufficient to form a homogeneous system, in which the lattice-substitution impurities and the charge carrier dopant impurities have diffused evenly throughout three-component melted region 412. In one embodiment, three-component melted region 412 is generated for a duration in the range of 10 nanoseconds-1000 nanoseconds.

Referring to FIG. 4E, the structure formed in association with FIG. 4D may be cooled below the melting temperature of three-component melted region 412 to re-solidify and form an epitaxial three-component re-growth region 414. In one embodiment, three-component re-growth induces a tensile strain on crystalline substrate 402. In another embodiment, three-component re-growth region 414 has a lattice constant larger than the lattice constant of crystalline substrate 402 and induces a compressive strain on crystalline substrate 402. In one embodiment, three-component re-growth region is a homogeneous epitaxial silicon film comprised of carbon lattice-substitution impurities in a concentration range of 1%-3% of the total film atomic composition and phosphorus charge carrier dopant impurities with a concentration in the range of 2E19 atoms/cm³-2E21 atoms/cm³. In one embodiment, the top surface of three-component re-growth region 412 is raised above the top surface of crystalline substrate 402, as depicted in FIG. 4E.

The formation by liquid-phase epitaxial re-growth of a three-component epitaxial film may be utilized in the fabrication of a semiconductor device. In one embodiment, the semiconductor device is a MOS-FET, a bipolar transistor, a memory transistor or a micro-electronic machine (MEM). In another embodiment, the semiconductor device is a planar device or a non-planar device, such as a tri-gate or double-gate transistor. For illustrative purposes, the fabrication of an NMOS-FET device incorporating the formation by liquid-phase epitaxial re-growth of a strain-inducing three-component epitaxial film is described below, in accordance with one embodiment of the present invention.

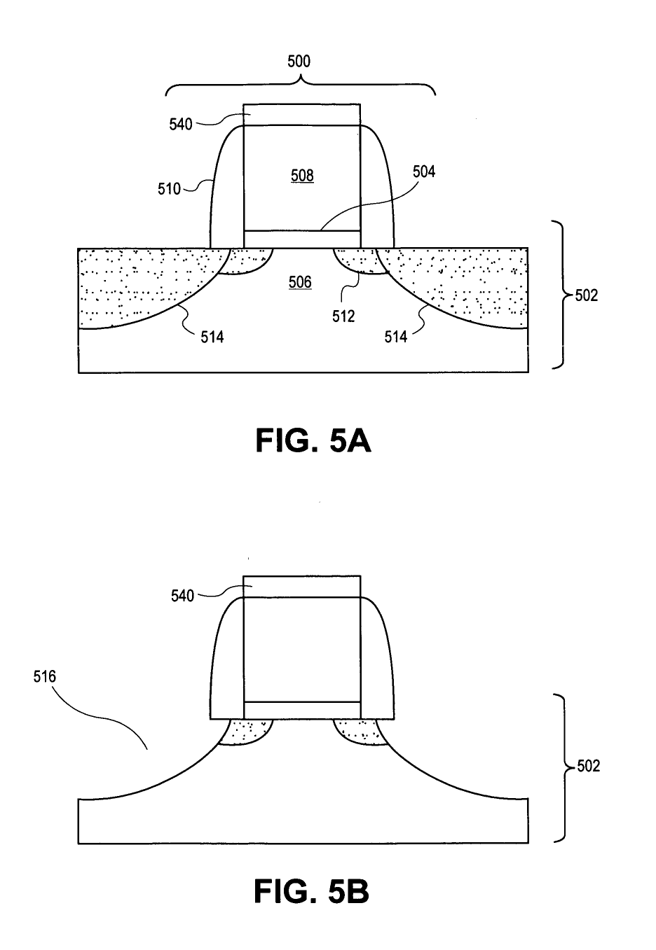

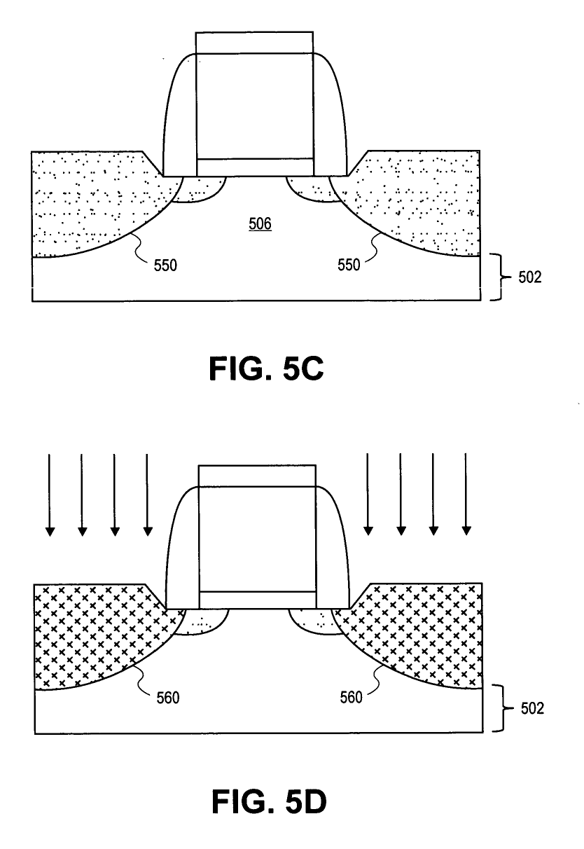

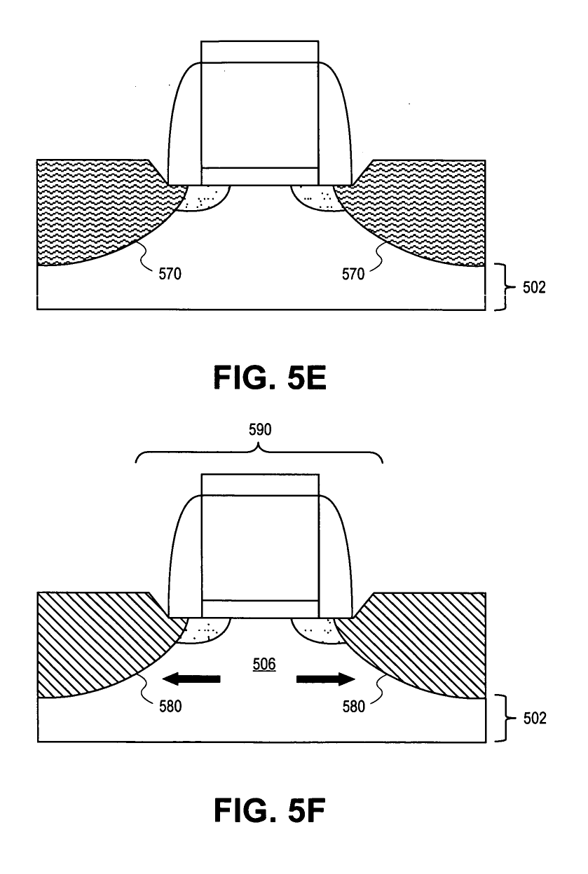

FIGS. 5A-F illustrate a process flow for forming strain-inducing source/drain regions in an NMOS-FET, in accordance with an embodiment of the present invention. Referring to FIG. 5A, a non-strained NMOS-FET 500 is first formed. Non-strained NMOS-FET 500 may be comprised of a channel region 506 in a crystalline substrate 502. In one embodiment of the present invention, crystalline substrate 502 is comprised of crystalline silicon. In another embodiment, crystalline substrate 502 is comprised of an epitaxial silicon layer grown atop a distinct crystalline silicon substrate. In one embodiment, crystalline substrate 502 is comprised of germanium or a III-V material such as but not limited to gallium nitride, gallium phosphide, gallium arsenide, indium phosphide or indium antimonide.

A gate dielectric layer 504 may be formed above channel region 506. In one embodiment, gate dielectric layer 504 is formed by a thermal oxidation process and is comprised of silicon dioxide or silicon oxy-nitride. In another embodiment, gate dielectric layer 504 is formed by chemical vapor deposition or atomic layer deposition and is comprised of a high-k dielectric layer such as, but not limited to, hafnium oxide, zirconium oxide, hafnium silicate, hafnium oxy-nitride or lanthanum oxide.

A gate electrode 508 may be formed above gate dielectric layer 504. Gate electrode 508 may be formed by a subtractive etching process scheme or by a replacement gate process scheme. In one embodiment, gate electrode 508 is comprised of a polycrystalline silicon gate electrode, wherein the charge carrier dopant impurities are implanted during fabrication of the tip and source/drain regions, described below. In another embodiment, gate electrode 508 is comprised of a metal layer such as but not limited to metal nitrides, metal carbides, hafnium, zirconium, titanium, tantalum, aluminum, ruthenium, palladium, platinum, cobalt, nickel or conductive metal oxides, e.g. ruthenium oxide. In one embodiment, a protective layer 540 is retained above gate electrode 508, as depicted in FIG. 5A.

A tip extension 512 may be formed by implanting charge carrier dopant impurity atoms into substrate 502. Gate electrode 508 may act to mask a portion of substrate 502 to form self-aligned tip extensions 512. In one embodiment, boron, arsenic, phosphorus, indium or a combination thereof is implanted into substrate 502 to form tip extension 512.

Gate dielectric layer 504 and gate electrode 508 may be isolated by gate isolation spacer 510. Gate isolation spacer 510 may be formed by any suitable technique. In an embodiment, an insulating layer such as but not limited to silicon dioxide, silicon nitride, silicon oxy-nitride or dry etched. In another embodiment, the thickness of the insulating layer is selected to determine the final width of gate isolation spacer 510. In one embodiment, gate isolation spacer 510 forms a hermetic seal with gate electrode 508 and the top surface of substrate 502 in order to encapsulate gate dielectric layer 504.

A source/drain region 514 may be formed by implanting charge carrier dopant impurity atoms into substrate 502. Thus, source/drain region 514 may be formed from the same material as channel region 506. Therefore, the lattice mismatch between source/drain region 514 and channel region 506 may be negligible, resulting in effectively no strain induced on channel region 506. Gate isolation spacer 510 and gate electrode 508 may act to shield a portion of substrate 502 during the implant step to form self-aligned source/drain regions 514. In effect, the thickness of gate isolation spacer 510 may play a role in dictating the dimensions of source/drain region 514. In one embodiment, boron, arsenic, phosphorus, indium or a combination thereof is implanted into substrate 502 to form source/drain regions 514.

Referring to FIG. 5B, portions of substrate 502, including source/drain regions 514, may be removed to form recessed region 516 in substrate 502. Recessed region 516 may be formed by any suitable technique, such as a dry etch or a wet etch process. In one embodiment, SF₆ or NF₃ gas in a plasma etcher is used to form recessed region 516. In another embodiment, protective layer 540 protects gate electrode 508 during the formation of recessed region 516. In another embodiment, recessed region 516 is formed to a depth sufficient to remove the charge carrier dopant impurities implanted to form source/drain region 514, as depicted in FIG. 5B.

Referring to FIG. 5C, material region 550 may be formed selectively in recessed region 516. In one embodiment, material region 550 is an epitaxial silicon layer or an epitaxial carbon-doped silicon layer and channel region 506 is comprised of crystalline silicon. In another embodiment, material region 550 is comprised of amorphous silicon or carbon-doped silicon and channel region 506 is comprised of crystalline silicon. In an embodiment, material region 550 is an amorphous or epitaxial silicon or carbon-doped silicon layer, doped with phosphorus atoms in situ, formed in a crystalline substrate. In one embodiment, material region 550 is an epitaxial silicon layer or an epitaxial carbon-doped silicon layer that is subsequently made amorphous by implanting silicon atoms into material region 550 at a dose in the range of 5E13 atoms/cm²-5E15 atoms/cm² with an energy in the range of 1 keV-50 keV. In another embodiment, material region 550 is made amorphous at the time of implanting charge-neutral lattice-impurities or charge carrier dopant impurities. In one embodiment, the top surface of material region 550 is raised above the top surface of substrate 502, and hence above the top surface of channel region 506, as depicted in FIG. 5C.

Referring to FIG. 5D, charge-neutral lattice-impurities and charge carrier dopant impurities may be implanted into material region 550 to form three-component amorphous region 560 in substrate 502. In one embodiment, material region 550 is comprised of silicon, the charge-neutral lattice-substitution impurities are carbon atoms and the charge carrier dopant impurities are phosphorus atoms. In another embodiment, material region 550 is comprised of carbon-doped silicon and phosphorus dopant atoms are added to form three-component amorphous region 560. In one embodiment, the concentration of lattice-substituting carbon atoms is in the range of 1%-3% of the total film atomic composition and the concentration of the phosphorus charge carrier dopant impurities is in the range of 2E19 atoms/cm³-2E21 atoms/cm³. In one embodiment, the lattice-substitution impurities and the charge carrier dopant impurities are implanted to a depth shallower than the amorphized portion of three-component amorphous region 560.

The structure formed in association with FIG. 5D may then be heated to a temperature sufficient to melt three-component amorphous region 560, but less than the temperature at which substrate 502 melts. Referring to FIG. 5E, three-component amorphous region 560 may be heated to form three-component melted region 570 within substrate 502. In one embodiment, three-component amorphous region 560 contains silicon, carbon and phosphorus atoms and is heated to a temperature of at least 1150° C. (to form three-component melted region 570), but not exceeding 1400° C. In another embodiment of the present invention, three-component amorphous region 560 is melted to form three-component melted region 570 by using a thermal annealing process or a laser irradiation process. Three-component melted region 570 may be generated for a duration sufficient to form a homogeneous system, in which the lattice-substitution impurities and the charge carrier dopant impurities have diffused evenly throughout three-component melted region 570. In one embodiment, three-component melted region 570 is generated for a duration in the range of 10 nanoseconds-1000 nanoseconds.

Referring to FIG. 5F, the structure formed in association with FIG. 5E may be cooled below the melting temperature of three-component melted region 570 to re-solidify and form three-component epitaxial re-growth region 580. In one embodiment, three-component epitaxial re-growth region 580 has a lattice constant smaller than the lattice constant of substrate 502, and hence channel region 506, and induces a tensile strain on channel region 506. In one embodiment, three-component epitaxial re-growth region is a homogeneous epitaxial silicon film comprised of carbon lattice-substitution impurities in a concentration range of 1%-3% of the total film atomic composition and phosphorus charge carrier dopant impurities with a concentration in the range of 2E19 atoms/cm³-2E21 atoms/cm³. Three-component epitaxial re-growth region 580 may function as a source/drain region and thus NMOS-FET 590 in FIG. 5F may comprise strain-inducing source/drain regions. Therefore, a uniaxial tensile strain, depicted by the arrows in FIG. 5F, may be rendered on channel region 506 in NMOS-FET 590, which can enhance electron mobility in the device. In one embodiment, the top surface of three-component epitaxial re-growth region 580 is raised above the top surface of substrate 502, and hence above the top surface of channel region 506, as depicted in FIG. 5F. NMOS-FET 590 may subsequently be integrated into an integrated circuit by conventional process steps, as known in the art.

The present invention is not limited to the formation of NMOS-FET devices with invention, a PMOS-FET comprising strain-inducing source/drain regions may be fabricated in a manner similar to that depicted in FIGS. 5A-F. In an embodiment, a three-component re-growth region has a lattice constant larger than the lattice constant of the channel region and thus induces a compressive strain on the channel region. In one embodiment, three-component re-growth region is a homogeneous epitaxial silicon film comprised of germanium lattice-substitution impurities in a concentration range of 10%-30% of the total film atomic composition and boron charge carrier dopant impurities with a concentration in the range of 2E19 atoms/cm³-2E21 atoms/cm³.

Thus, a method to form a three-component epitaxial film has been disclosed. In an embodiment, the three-component epitaxial film comprises atoms from a parent film, charge-neutral lattice-substitution impurities and charge carrier dopant impurities. In one embodiment, the charge-neutral lattice-substitution impurities are smaller and present in greater concentration than the charge carrier dopant impurities. In one embodiment, the charge-neutral lattice-substitution impurities are larger and present in greater concentration than the charge carrier dopant impurities. In another embodiment, a strain-inducing epitaxial film comprises a three-component epitaxial film. In one embodiment, formation of the strain-inducing epitaxial film by liquid-phase epitaxial re-growth enables a much higher strain and doping activation than that achieved by other methods.

What is claimed is:

1. A method of forming a semiconductor structure comprising:
forming an amorphous region in a crystalline substrate;
heating said amorphous region and said crystalline substrate to a temperature sufficient to melt said amorphous region, but insufficient to melt said crystalline substrate, to form a melted region in said crystalline substrate; and
cooling said melted region and said crystalline substrate to a temperature sufficient to re-solidify said melted region to form an epilaxial re-growth region in said crystalline substrate.

2. The method of claim 1 wherein said epitaxial re-growth region comprises charge neutral lattice-substitution impurity atoms and has a smaller lattice constant than said crystalline substrate.

3. The method of claim 1 wherein said epitaxial re-growth region comprises charge neutral lattice-substitution impurity atoms and charge carrier dopant impurity atoms.

4. The method of claim 3 wherein said charge neutral lattice-substitution impurity atoms are smaller and present in greater concentration than said charge carrier dopant impurity atoms.

5. The method of claim 1 wherein said crystalline substrate is comprised of silicon and said epitaxial re-growth region is comprised of carbon lattice-substitution impurity atoms and phosphorus charge carrier dopant impurity atoms.

6. The method of claim 5 wherein the concentration of said carbon lattice-substitution impurity atoms is in the range of 1%-3% of the total atomic composition of said epitaxial re-growth region and the concentration of said phosphorus charge carrier dopant impurity atoms is in the range of 2E19 atoms/cm³-2E21 atoms/cm³.

7. A method of forming a semiconductor structure comprising:
removing a portion of a crystalline substrate to form an etched-out region in said crystalline substrate;
forming a material region in said etched-out region;
amorphizing said material region to form an amorphized in said crystalline substrate;
heating said amorphized region and said crystalline substrate to a temperature sufficient to melt said amorphized region, but insufficient to melt said crystalline substrate, to form a melted region in said crystalline substrate; and
cooling said melted region and said crystalline substrate to a temperature sufficient to re-solidify said melted region to form an epitaxial re-growth region in said crystalline substrate.

8. The method of claim 7 wherein said epitaxial re-growth region has a smaller lattice constant than said crystalline substrate.

9. The method of claim 7 wherein said epitaxial re-growth region comprises charge neutral lattice-substitution impurity atoms and charge carrier dopant impurity atoms.

10. The method of claim 9 wherein said charge neutral lattice-substitution impurity atoms are smaller and present in greater concentration than said charge carrier dopant impurity atoms.

11. The method of claim 7 wherein said crystalline substrate is comprised of silicon, said material region is comprised of silicon, and said epitaxial re-growth region is comprised of carbon lattice-substitution impurity atoms and phosphorus charge carrier dopant impurity atoms.

12. The method of claim 11 wherein the concentration of said carbon lattice-substitution impurity atoms is in the range of 1%-3% of the total atomic composition of said epitaxial re-growth region and the concentration of said phosphorus charge carrier dopant impurity atoms is in the range of 2E19 atoms/cm³-2E21 atoms/cm³.

13. A method of forming a semiconductor device comprising:
forming a gate dielectric layer above a channel region in a crystalline substrate;
forming a gate electrode above said gate dielectric layer;
forming a source/drain region in said crystalline substrate;
removing a portion of said crystalline substrate, including said source/drain region, to form an etched-out region in said crystalline substrate;
forming a material region in said etched-out region;
amorphizing said material region to form an amorphized region in said crystalline substrate;
providing charge-neutral lattice-substitution impurity atoms and charge carrier dopant impurity atoms to form a three-component amorphous region in said crystalline substrate;
heating said three-component amorphous region and said crystalline substrate to a first temperature sufficient to melt said three-component amorphous region, but insufficient to melt said crystalline substrate, to form a three-component melted region in said crystalline substrate; and
cooling said three-component melted region and said crystalline substrate to a second temperature sufficient to re-solidify said three-component melted region to form a three-component epitaxial re-growth region in said crystalline substrate.

14. The method of claim 13 wherein said three-component epitaxial re-growth region has a smaller lattice constant than said crystalline substrate.

15. The method of claim 13 wherein said charge neutral lattice-substitution impurity atoms are smaller and provided in greater concentration than said charge carrier dopant impurity atoms.

16. The method of claim 13 wherein said crystalline substrate is comprised of silicon, said material region is comprised of silicon, and said three-component epitaxial re-growth region is comprised of carbon lattice-substitution impurity atoms and phosphorus charge carrier dopant impurity atoms.

17. The method of claim 16 wherein the concentration of said carbon lattice-substitution impurity atoms is in the range of 1%-3% of the total atomic composition of said three-component epitaxial re-growth region and the concentration of said phosphorus charge carrier dopant impurity atoms is in the range of 2E19 atoms/cm³-2E21 atoms/cm³.

18. The method of claim 16 wherein said first temperature is at least 1150° C., but does not exceed 1400° C.

19. The method of claim 18 wherein said three-component melted region is generated for a duration in the range of 10 nanoseconds-1000 nanoseconds.

20. The method of claim 13 wherein said three-component melted region is generated for a duration sufficient to form a homogeneous system, wherein said lattice-substitution impurity atoms and said charge carrier dopant impurity atoms are diffused evenly throughout said three-component melted region.
